(19) United States
(12) Patent Application Publication
(10) Pub. No.: US 2018/0096796 A1
(43) Pub. Date: Apr. 5, 2018

(54) PEROVSKITE-BASED OPTOELECTRONIC DEVICE EMPLOYING NON-DOPED SMALL MOLECULE HOLE TRANSPORT MATERIALS

(71) Applicant: The Regents of the University of California, Oakland, CA (US)

(72) Inventors: Yang Yang, Los Angeles, CA (US); Yongsheng Liu, Los Angeles, CA (US); Qi Chen, Los Angeles, CA (US); Huanping Zhou, Los Angeles, CA (US)

(73) Assignee: The Regents of the University of California, Oakland, CA (US)

(21) Appl. No.: 15/567,721

(22) PCT Filed: Apr. 20, 2016
(86) PCT No.: PCT/US16/28440

§ 371 Date: Oct. 19, 2017

Related U.S. Application Data
(60) Provisional application No. 62/150,108, filed on Apr. 20, 2015.

(51) Int. Cl. H01G 9/20; H01G 9/00; H01L 51/00; H01L 51/42; H01L 51/44

(52) U.S. Cl. CPC H01G 9/2018; H01G 9/0029; H01G 9/2095; H01L 51/0003; H01L 51/001; H01L 51/0077; H01L 51/4253; H01L 51/441; H01L 51/0074; H01L 51/0069; H01L 51/0068; H01L 51/0097

(57) ABSTRACT

An optoelectronic device includes a first electrode, a second electrode spaced apart from the first electrode, a photoactive layer that includes an organic-inorganic hybrid perovskite material disposed between the first and second electrodes, and a layer of a hole transport material disposed between the photoactive layer and one of the first and second electrodes. A method of producing an optoelectronic device includes forming a photoactive layer of an organic-inorganic perovskite using at least one of solution processing or thermal vacuum deposition, and depositing a layer of hole transport material on the photoactive layer using at least one of solution processing or thermal vacuum deposition. The hole transport material includes non-doped donor-acceptor (D-A) conjugated small molecules.

### CROSS-REFERENCE OF RELATED APPLICATION

This application claims priority to U.S. Provisional Application No. 62/150,108 filed Apr. 20, 2015, the entire content of which is hereby incorporated by reference.

### BACKGROUND

### 1. Technical Field

The field of the currently claimed embodiments of this invention relates to organic-inorganic hybrid devices and methods of preparing optoelectronic devices using non-doped small molecules as hole transport materials (HTMs), and in particularly the present invention relates to perovskite-based solar cells and a method for preparing perovskite-based solar cells using non-doped small molecules as HTMs.

### 2. Discussion of Related Art

Organic-inorganic hybrid materials, particularly including materials of the perovskite family, represent an alternative class of materials that may combine desirable physical properties characteristic of both organic and inorganic components within a single molecular-scale composite. Organic-inorganic hybrid materials have applications in photovoltaics and field-effect transistors, and also have potential to be incorporated into lasers, light-emitting diodes, and other sensors, such as radiation detectors.

Solar energy is the cleanest and most abundant renewable energy source available in the world, and it is getting an incredible amount of attention. One of the most effective approaches to utilize solar energy is via photovoltaic technology that can directly convert sunlight into electricity. At present, most of the commercial solar cells are based on inorganic materials such as silicon. However, these very expensive materials and energy consuming processing techniques hinder their use. To produce low-cost and large area solar cells, many new device structures and materials are being developed.

Recently, organometal halide perovskites, such as CH₃NH₃PbI₃ with three-dimensional structures, have been used as light absorbers for solar cells and have shown high performance due to its direct band gap of 1.5 eV, large absorption coefficient and very high charge carrier mobility. For the lead halide based organic-inorganic hybrid solar cells, HTMs are needed for hole extraction and transport. To date, only a few materials have been demonstrated to be effective HTMs for hybrid solar cells with good performance, among which spiro-OMeTAD is the most effective material. Using spiro-OMe-TAD as a hole conductor, Gratzel et al. recently constructed a TiO₂/CH₃NH₃PbI₃ based solar cell demonstrating 15.0% efficiency, and Snaith et al. reported a planar TiO2/CH3NH3PbI_{(3-X)}Cl_{X} based solar cell with a record efficiency of 15.4%.

Despite offering the best performance yet achieved as HTMs for persovskite solar cells, spiro-MeOTAD suffers from a low hole mobility (˜10⁻⁴ cm² V⁻¹s⁻¹) and low conductivity (˜10⁻⁵ S cm⁻²) in its pristine form. As the conductivity of a typical halide perovskite is on the order of 10⁻³ S cm⁻¹, the spiro-OMeTAD layer should be thick enough to prevent an electrical short circuit between the perovskite layer and the counter electrode. While, thick spiro-OMeTAD layer will result a high series resistance and low fill factor. Thus, additional additives or p-type dopants, such as lithium bis(trifluoromethylsulfonyl)-imide (Li-TFSI), are required for spiro-MeOTAD HTMs to increase its conductivity and hole mobility. HTMs with higher conductivity will reduce series resistance and improve the fill factor of the hybrid solar cells. Spiro-OMeTAD likely does not represent the ideal hole-conducting material for this system due to its disadvantages such as: (1) spiro-OMeTAD is very expensive due to the synthetic methods and high purity needed for photovoltaic applications; (2) the device using spiro-OMeTAD as HTMs requires exposure to ambient atmosphere for proper functioning, thus at the same time risking degrading the perovskite; (3) the hydrophilic nature of spiro-OMeTAD will have a negative effect on the stability of the perovskite-based hybrid solar cells.

Therefore there remains a need for improved organic-inorganic hybrid devices and methods of production.

### SUMMARY

An optoelectronic device according to an embodiment of the current invention includes a first electrode, a second electrode spaced apart from the first electrode, a photoactive layer that includes an organic-inorganic hybrid perovskite material disposed between the first and second electrodes, and a layer of a hole transport material disposed between the photoactive layer and one of the first and second electrodes. The hole transport material includes non-doped donor-acceptor (D-A) conjugated small molecules.

A method of producing an optoelectronic device according to an embodiment of the current invention includes forming a photoactive layer of an organic-inorganic perovskite using at least one of solution processing or thermal vacuum deposition, and depositing a layer of hole transport material on the photoactive layer using at least one of solution processing or thermal vacuum deposition. The hole transport material includes non-doped donor-acceptor (D-A) conjugated small molecules.

### BRIEF DESCRIPTION OF THE DRAWINGS

Further objectives and advantages will become apparent from a consideration of the description, drawings, and examples.

FIG. 1 shows chemical structures of some examples of small molecules used as HTMs for perovskite solar cells according to some embodiments of the current invention.

FIG. 2 is a schematic illustration of a device structure of perovskite solar cells using non-doped small molecule as HTM according to an embodiment of the current invention.

FIG. 3A shows an SEM image of CH₃NH₃PbI_{(3-X)}Cl_{X} on TiO₂ film. FIG. 3B shows an SEM image of non-doped DOR3T-TBDT on CH₃NH₃PbI_{(3-X)}Cl_{X} film.

FIG. 4 shows a J-V curve of a perovskite-based solar cell using DOR3T-BDTT as HTM according to an embodiment of the current invention.

### DETAILED DESCRIPTION

Some embodiments of the current invention are discussed in detail below. In describing embodiments, specific terminology is employed for the sake of clarity. However, the invention is not intended to be limited to the specific terminology so selected. A person skilled in the relevant art will recognize that other equivalent components can be employed and other methods developed without departing from the broad concepts of the current invention. All references cited anywhere in this specification, including the Background and Detailed Description sections, are incorporated by reference as if each had been individually incorporated.

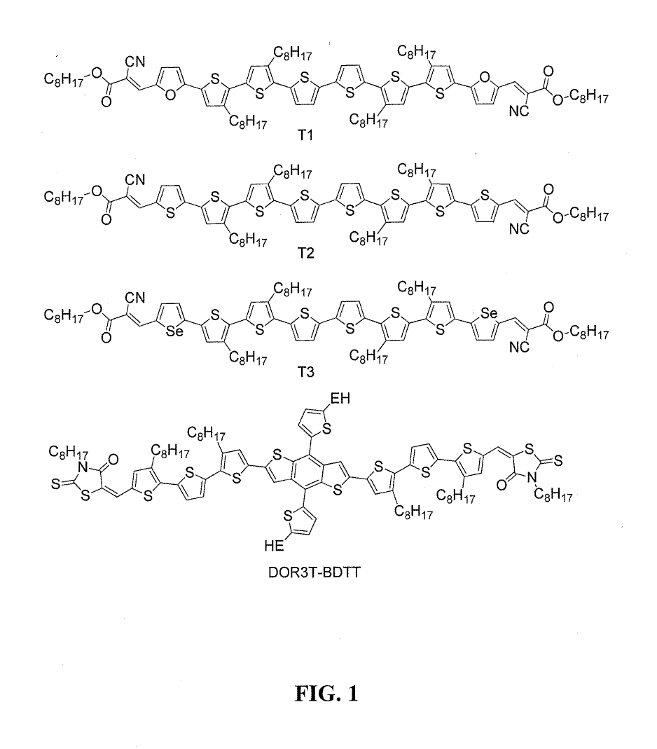

Accordingly, the development of alternative hole transport materials instead of spiro-OMeTAD is a promising avenue to further improve the performance and fabrication of perovskite solar cells. Few such materials are available. Seok et al. introduce a doped polymeric hole conductor poly-(triarylamine) (PTAA) for perovskites based organic-inorganic hybride solar cells that substantially improves the open-circuit voltage Voc and fill factor of the cells, yielding a power conversion efficiency of 12.0% under standard AM 1.5G conditions. In addition, several conducting polymers such as P3HT, PCBTDPP, PCPDTBT and PCDTBT have also been used as HTMs for perovskite solar cells. However, the high cost of hole transport materials and/or low performance and/or doping requirement hinders the advancement of cost-effective and practical perovskite solar cells. Donor-Acceptor (D-A) conjugated small molecules are an appropriate choice as HTMs and have been widely used as active conductive materials in electronic devices owing to their tunable optical and electrical properties, ease of synthesis and purification, and a low production cost and versatile wet processing procedures. Organic field effect transistors (OFETs), organic light-emitting diodes (OLEDs), and organic bulk heterojunction (BHJ) solar cells have been successfully prepared using numerous D-A conjugated small molecules, with remarkable performances. As HTMs, conjugated D-A small molecules can have advantages, such as: (1) free of doping requirements for applications; (2) tunable oxidation potential thus ease of obtaining compatible HOMO (the highest occupied molecule orbital) energy level to the perovskite absorbers; (3) allowing the full device fabrication to be done in a nitrogen atmosphere, thereby protecting the humidity-sensitive perovskite; and (4) non-doped D-A conjugated small molecules HTMs with hydrophobicity will prevent water permeation into the perovskite surface, thus improving the stability of the devices. Recently, we have designed and synthesized a class of solution processable small molecules using furan, thiophene and selenophene as electron linkers (FIG. 1) for application in BHJ OSCs. We show that the variation of the electron linkers enables fine-tuning of the optical energy gap as well as of the HOMO and LUMO levels. All these small molecules show high PCEs, ranging from 3.18-6.15% under simulated AM 1.5G condition (100 mW cm⁻²), and the highest PCE of 6.15% was achieved for a T3/PC₇₁BM based device using PDMS as additive. We also successfully demonstrated high-efficiency solution-processed single junction and double junction tandem OSCs based on a 2-D conjugated small molecule DOR3T-BDTT (FIG. 1). Single junction device based on DOR3T-BDTT/PC₇₁BM exhibited a certified PCE of 8.02% under AM1.5G condition (100 mW cm⁻²), as measured by Newport Corporation. Note that the HOMO level of DOR3T-BDTT is 5.5 eV, which is compatible with the HOMO level of organo-lead halide perovskite. These demonstrations are indicative of the application potential of these small molecules as HTMs for hybrid solar cells.

Some embodiments of the current invention provide efficient organic-inorganic perovskite solar cells, using optical and energy-level tunable, low-cost hole transport organic materials.

An embodiment of the current invention provides a perovskite-based optoelectronic device comprising non-doped D-A conjugated small molecule HTMs, wherein the HTMs include, but are not limited to, D-A conjugated small molecules. FIG. 1 shows some D-A small molecules we developed that are suitable for perovskite solar cells as HTMs. The HTMs include but not limited to these small molecules.

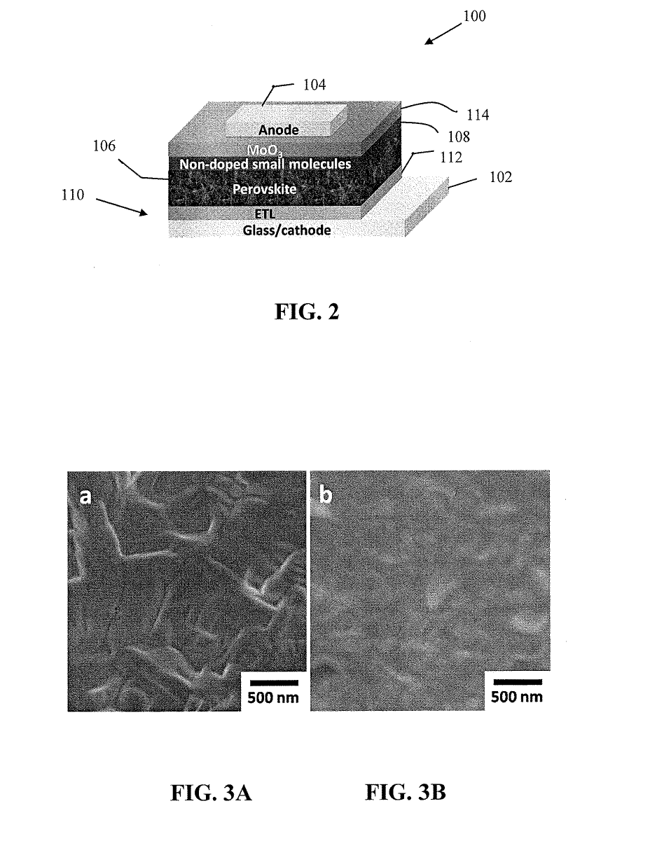

FIG. 2 is a schematic illustration of an optoelectronic device 100 according to an embodiment of the current invention. The particular materials described, such as Glass and MoO₃ are examples and not required according to the general concepts of the current invention. The optoelectronic device 100 includes a first electrode 102, a second electrode 104 spaced apart from said first electrode 102, a photoactive layer 106 including an organic-inorganic hybrid perovskite material disposed between the first and second electrodes (102, 104), and a layer of a hole transport material 108 disposed between the photoactive layer 106 and one of the first and second electrodes (102, 104). The hole transport material 108 includes non-doped donor-acceptor (D-A) conjugated small molecules.

In some embodiments, the first electrode 102 can be formed on, or be considered part of, a substrate 110. In addition, an electron transport layer 112 can be formed on the substrate 110 in some embodiments. In further embodiments, a p-type metal oxide layer 114 can be formed on the layer of a hole transport material 108.

The perovskite used here refers to a material with a three-dimensional crystal structure related to that of CaTiO₃. The perovskite structure can be represented by the formula ABX₃, wherein A and B are cations of different sizes and X is an anion. Usually, [A] is an organic cation and [B] is metal cation. Usually, [B] comprises Pb²⁺ or Sn²⁺ and [X] comprises a halide anion or a mixed halide anion. More typically, [B] comprises Pb²⁻, and [X] comprises I⁻.

Another embodiment of the present invention provides a process for fabrication of an organic-inorganic perovskite-based device using non-doped small molecule HTMs. An embodiment particularly provides a process for fabrication of organic-inorganic perovskite-based solar cells using non-doped small molecule HTMs. An embodiment of the present invention can include, but is not limited to, solar cells that have the inverted structure. As an example, for the inverted structure, a method of producing a solar cell according to an embodiment of the current invention includes:
1) Depositing the ETLs, such as TiO2, on the desired substrates to form a thin film framework, via solution processing or thermal vacuum deposition.
2) Fabricating the organic-inorganic perovskite solid films on top of ETL via solution processing or thermal vacuum deposition to form a light absorber layer.
3) Depositing the non-doped D-A small molecule HTM on the surface of perovskite film via solution processing or thermal vacuum deposition.
4) Depositing p-type metal oxide and metal electrode in sequence on the top of HTM via solution processing or thermal vacuum deposition.

The schematic illustration of the inverted device structure is shown in FIG. 2. However, the general concepts of the current invention are not limited to only photovoltaic cells of the inverted structure.

The D-A conjugated small molecule can be used directly as HTMs without doping. The HTMs used here can form a continuous film with up to 100% surface coverage of the perovskite film. Preferably, the organic-inorganic perovskite material has a high conductivity and is a polycrystalline material having a grain size equal to or greater than the dimensions between contacts in a device. It is preferred to form the HTM with good surface coverage and small surface roughness to prevent an electrical short circuit between the perovskite layer and the counter electrode.

As such, suitable HTMs include, but are not limited to, D-A conjugated small molecules. Particularly, the HTMs include the small molecules in FIG. 1, but not limited to these small molecules. The donor units include, but are not limited to the electron rich units, such as thiophene, selenophene, furan, dithienopyran (DTP), dithienosilole (DTS), dithienogermole (DTG), benzo[1,2-b:4,5-b′]dithiophene (BDT), alkylthienylbenzodithiophene (BDTT), and so on. The acceptor units include, but are not limited to the electron-deficient units, such as dicyanovinyl, alkyl cyanoacetate, 3-alkylrodanine, 2,1,3-benzothiadiazole, 5-fluorobenzo-2,1,3-thiadiazole, difluorobenzothiadiazole (DFBT), fluorine substitute thieno[3,4-b]thiophene (F-TT), N-alkyl-thienopyrrolodione (TPD) and diketopyrrolopyrrole (DPP), and so on. The HTMs fabrication methods include, but are not limited to spin-coating, spray-coating, dip-coating, slot die coating, inkjet printing and thermal vacuum deposition. The film thickness of HTMs can be 20 nanometers to several hundred nanometers.

The materials used in the device of the invention are inexpensive, easy to synthesize and purify. Further, the methods of producing the device using these hole transport materials are suitable for large-scale production.

A variety of different substrates can be used, such as, but not limited to, FTO, ITO, silicon, metal, oxides, polymers, and etc. The flexibility in the chemistry, and processing of non-doped small molecule HTM facilitates perovskite based devices being incorporated into different applications: such as solar cells and LED. In addition, flexible substrates can be used to make flexible electronics.

Some aspects of the current invention are directed to the following:
1. The hole transport materials (HTMs) used here are Non-doped donor-acceptor (D-A) conjugated small molecules.
2. Suitable HTMs can include, but are not limited to, D-A conjugated small molecules. The donor units can include, but are not limited to, electron rich units, such as thiophene, selenophene, furan, dithienopyran (DTP), dithienosilole (DTS), dithienogermole (DTG), benzo[1,2-b:4,5-b′]dithiophene (BDT), alkylthienylbenzodithiophene (BDTT), and so on. The acceptor units can include, but not limited to, electron-deficient units, such as dicyanovinyl, alkyl cyanoacetate, 3-alkylrodanine, 2,1,3-benzothiadiazole, 5-fluorobenzo-2,1,3-thiadiazole, difluorobenzothiadiazole (DFBT), fluorine substitute thieno[3,4-b]thiophene (F-TT), N-alkyl-thienopyrrolodione (TPD) and diketopyrrolopyrrole (DPP), and so on.
3. Perovskite materials used here are organic-inorganic hybrid perovskites. Particularly, the perovskite structure can be represented by the formula ABX₃, wherein A is an organic cation, B is an inorganic cation, and X is a halogen anion or mixed halogen anions.
4. Non-doped small molecule HTMs facilitate perovskite-based devices being incorporated into different applications: such as, but not limited to, solar cells, light emitting diodes, photodectors, and so on.

The following examples describe some embodiments in more detail. The broad concepts of the current invention are not intended to be limited to the particular examples.

### EXAMPLES

### Example 1

The non-doped small molecule (DOR3T-BDTT) HTM with the thickness from 20 nm to several hundred nano-meters on top of perovskite film was fabricated. Several different substrates are employed, such as FTO, ITO, TiO₂, SiO₂, Si and ZnO. The following two figures shows the SEM image of CH₃NH₃PbI_{(3-X)}Cl_{X} film on the TiO₂ surface and the non-doped small-molecule films on the surface of the CH₃NH₃PbI_{(3-X)}Cl_{X}/TiO2 film.

### Example 2

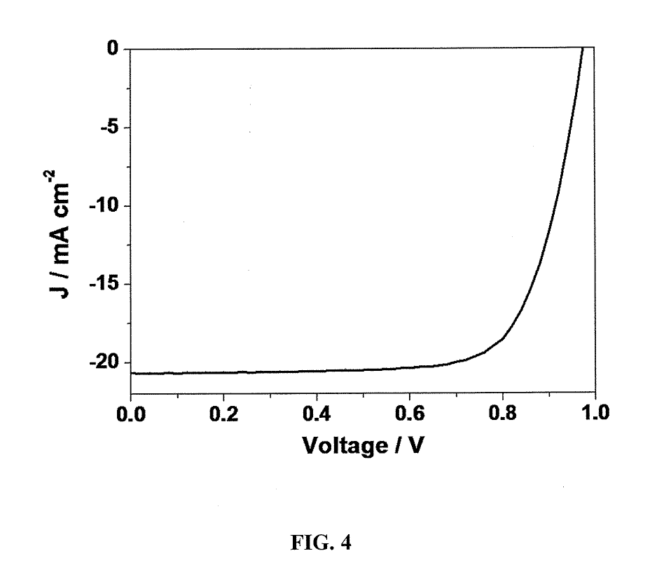

We fabricated the solar cells using mixed halide perovskite compounds (CH₃NH₃Pb_{(3-X)}Cl_{X}) as light absorber and our small molecule DOR3T-BDTT as HTMs or electron-blocking layers. The device consists of the following components: ITO/TiO₂/CH₃NH₃Pb_{(3-X)}Cl_{X}/DOR3T-BDTT/MoO3/Ag. Here TiO₂ nanoparticles were used as electron transport layers (ETLs) or hole-blocking layers. The resulting devices showed a PCE up to 14.93% with an incident photon to current efficiency (IPCE) of 84% at a wavelength of 510 nm. The J-V curve is shown in FIG. 4.

The embodiments illustrated and discussed in this specification are intended only to teach those skilled in the art how to make and use the invention. In describing embodiments of the invention, specific terminology is employed for the sake of clarity. However, the invention is not intended to be limited to the specific terminology so selected. The above-described embodiments of the invention may be modified or varied, without departing from the invention, as appreciated by those skilled in the art in light of the above teachings. It is therefore to be understood that, within the scope of the claims and their equivalents, the invention may be practiced otherwise than as specifically described.

1. An optoelectronic device, comprising:
a first electrode;
a second electrode spaced apart from said first electrode;
a photoactive layer comprising an organic-inorganic hybrid perovskite material disposed between said first and second electrodes; and
a layer of a hole transport material disposed between said photoactive layer and one of said first and second electrodes,
wherein said hole transport material comprises non-doped donor-acceptor (D-A) conjugated small molecules.

2. The optoelectronic device according to claim 1, wherein a donor unit of said non-doped donor-acceptor (D-A) conjugated small molecules comprises electron rich units.

3. The optoelectronic device according to claim 2, wherein said electron rich units are at least one of thiophene, selenophene, furan, dithienopyran (DTP), dithienosilole (DTS), dithienogermole (DTG), benzo[1,2-b:4,5-b′]dithiophene (BDT), and alkylthienylbenzodithiophene (BDTT).

4. The optoelectronic device according to claim 1, wherein an acceptor unit of said non-doped donor-acceptor (D-A) conjugated small molecules comprises electron-deficient units.

5. The optoelectronic device according to claim 4, wherein said electron-deficient units comprise at least one of dicyanovinyl, alkyl cyanoacetate, 3-alkylrodanine, 2,1,3-benzothiadiazole, 5-fluorobenzo-2,1,3-thiadiazole, difluorobenzothiadiazole (DFBT), fluorine substitute thieno[3,4-b]thiophene (F-TT), N-alkyl-thienopyrrolodione (TPD) and diketopyrrolopyrrole (DPP).

6. The optoelectronic device according to claim 1, wherein said organic-inorganic hybrid perovskite material satisfies the formula ABX₃, wherein A is an organic cation, B is an inorganic cation, and X is a halogen anion or mixed halogen anions.

7. The optoelectronic device according to claim 1, further comprising an electron transport layer disposed between said photoactive layer and the other one of said first and second electrodes on an opposite side relative to said layer of said hole transport material.

8. The optoelectronic device according to claim 1, wherein said first electrode, said second electrode, said photoactive layer and said layer of hole transport material are all flexible layers such that said optoelectronic device is a flexible optoelectronic device.

9. A method of producing an optoelectronic device, comprising:
forming a photoactive layer of an organic-inorganic perovskite using at least one of solution processing or thermal vacuum deposition;
depositing a layer of hole transport material on said photoactive layer using at least one of solution processing or thermal vacuum deposition,
wherein said hole transport material comprises non-doped donor-acceptor (D-A) conjugated small molecules.

10. The method of claim 9, further comprising:
providing a substrate comprising an electrode;
depositing an electron transport layer on said substrate by at least one of solution processing or thermal vacuum deposition,
wherein said forming said photoactive layer is by depositing on said electron transport layer by at least one of solution processing or thermal vacuum deposition.

11. The method of claim 9, further comprising:
depositing a p-type metal oxide layer on said photoactive layer by at least one of solution processing or thermal vacuum deposition; and
forming a second electrode on said p-type metal oxide layer by at least one of solution processing or thermal vacuum deposition.

12. The method of according to claim 9, wherein said substrate is a flexible substrate.

13. The method of according to claim 9, wherein a donor unit of said non-doped donor-acceptor (D-A) conjugated small molecules comprises electron rich units.

14. The method of according to claim 13, wherein said electron rich units are at least one of thiophene, selenophene, furan, dithienopyran (DTP), dithienosilole (DTS), dithienogermole (DTG), benzo[1,2-b:4,5-b′]dithiophene (BDT), and alkylthienylbenzodithiophene (BDTT).

15. The method of according to claim 9, wherein an acceptor unit of said non-doped donor-acceptor (D-A) conjugated small molecules comprises electron-deficient units.

16. The method of according to claim 15, wherein said electron-deficient units comprise at least one of dicyanovinyl, alkyl cyanoacetate, 3-alkylrodanine, 2,1,3-benzothiadiazole, 5-fluorobenzo-2,1,3-thiadiazole, difluorobenzothiadiazole (DFBT), fluorine substitute thieno[3,4-b]thiophene (F-TT), N-alkyl-thienopyrrolodione (TPD) and diketopyrrolopyrrole (DPP).

17. The method of according to claim 9, wherein said organic-inorganic hybrid perovskite material satisfies the formula ABX₃, wherein A is an organic cation, B is an inorganic cation, and X is a halogen anion or mixed halogen anions.
